(19) United States
(12) Patent Application Publication
(10) Pub. No.: US 2017/0162843 A1
(43) Pub. Date: Jun. 8, 2017

(54) Battery System with a Device for Closing a Housing of the Battery System

(71) Applicant: Robert Bosch GmbH, Stuttgart (DE)

(72) Inventors: Clemens Schupp, Gerlingen (DE); Mario Bleicher, Kirchheim (DE); Matthias Oechsle, Ditzingen-Hirschlanden (DE); Michael Wellm, Freiberg Am Neckar (DE); Stefan Baumann, Altenriet (DE)

(21) Appl. No.: 15/367,792

(22) Filed: Dec. 2, 2016

(30) Foreign Application Priority Data
Dec. 4, 2015 (DE) 10 2015 224 304.4

(51) Int. Cl. H01M 2/10; H01M 10/0525; H05K 5/02

(52) U.S. Cl. CPC H01M 2/1094; H05K 5/0226; H05K 5/0221; H01M 10/0525; H01M 2220/20

(57) ABSTRACT

A battery system, in particular a lithium-ion system, includes at least one battery device, at least one first housing element, at least one second housing element, and a closing device. The housing elements have a common connecting hinge that enables moving at least one of the housing elements about a common rotation axis, and are configured to move into a closed position whereat the housing elements define a common closed interior. The housing elements are also configured to receive the battery device. The closing device is configured to automatically move at least one of the housing elements about the common rotation axis into the closed position.

This application claims priority under 35 U.S.C. §119 to patent application no. DE 10 2015 224 304.4, filed on Dec. 4, 2015 in Germany, the disclosure of which is incorporated herein by reference in its entirety.

The present disclosure relates to a battery system and the use of the battery system.

### BACKGROUND

Battery systems are known from the prior art, wherein the battery systems have housing elements, wherein the housing elements are connectable and can receive battery devices. Thus for example, US 2012067914 A discloses a battery housing having a first housing half and a second housing half, wherein the first and second housing halves have a common hinge suitable for rotating the first housing half about a rotation axis.

Furthermore, US 2011049174 A discloses an electronic device having a housing, wherein a battery device may be arranged in the interior of the housing, wherein a part of the housing may be opened and is connected to a region of the housing via a hinge.

### SUMMARY

The disclosure is based on a battery system, in particular a lithium-ion battery system. The battery system contains at least one battery device and at least one first housing element and at least one second housing element. The at least one first housing element and the at least one second housing element are suitable for receiving at least one battery device. The at least one first housing element and the at least one second housing element may furthermore assume a closed position, such that the at least one first housing element and the at least one second housing element in the closed position form a common closed interior. Furthermore, the at least one first housing element and the at least one second housing element have a common connecting hinge, suitable for moving the at least one first housing element and/or the at least one second housing element about a common rotation axis.

The core of the disclosure is that the battery system comprises a closing device suitable for automatically moving the at least one first housing element and/or the at least one second housing element about the common rotation axis into the closed position.

Because of the fact that, according to the disclosure, the battery system comprises a closing device suitable for automatically moving the at least one first housing element and/or the at least one second housing element about the common rotation axis into the closed position, a simple mechanism is provided for reliable closure of a battery housing. An undesirable failure to close the battery housing, i.e. an undesirable failure of the at least one first housing element and the at least one second housing element to form a common closed interior, is avoided. In addition, on automatic movement of the at least one first housing element and/or the at least one second housing element about the common rotation axis into the closed position, the at least one first housing element or the at least one second housing element is guided and positioned precisely during the closing process. Furthermore, no further elements are required for locking, which leads to a reduction in the volume and weight of the battery system.

In particular, after maintenance work on the battery system, an undesirable failure to close the battery system is avoided. Because the closing device is automatic, an undesirable escape of substances from the battery system and an undesirable penetration of substances into the battery system are avoided. This leads to an increase in safety when handling a battery system and ensures the suitability for use of a battery system.

The battery system is preferably a rechargeable electrochemical energy accumulator. The battery system may contain, as well as the at least one battery device, devices for controlling the battery device, and preferably contact devices. The contact devices are in particular suitable for transferring electrical energy from the battery system to a consumer. The contact devices may be so-called terminals. The battery devices also have terminals for electrical contacting, in particular for mutual electrical contacting. The consumer may in particular be a motor vehicle.

The disclosure also comprises the use of a battery system in a vehicle, in particular in a motor vehicle.

Further advantageous embodiments of the disclosure are the subject of the claims, detailed description, and drawings.

According to an advantageous embodiment of the disclosure, the closing device is integrated in the hinge.

By integrating the closing device in the hinge according to the disclosure, for example space is saved inside the battery system. In addition, the closing device is better protected from mechanical stresses. Furthermore, the closing device has good accessibility and can therefore be easily maintained and monitored.

According to a next preferred embodiment of the disclosure, the closing device is a traction device or a pressure device.

According to a further preferred embodiment of the disclosure, the traction device comprises a spring, in particular a coil spring. Because the traction device is a spring and in particular a coil spring, an even pressure can be generated between the two housing elements.

According to a next preferred embodiment of the disclosure, the closing device is a vacuum device. Because the closing device is a vacuum device, an approximate vacuum can be created inside the interior formed by the two housing elements. This approximate vacuum holds the two housing elements together. According to this embodiment, no further locking elements are required. This leads to a reduction in the volume and weight of the battery system.

According to a next preferred embodiment of the disclosure, a sealing material is arranged on the at least one first housing element and/or on the at least one second housing element. The sealing material in particular is arranged at the region of the at least one first and/or second housing element which, in the closed position, is in contact with the at least one second or first housing element respectively.

Because a sealing material is arranged according to the disclosure on the at least one first housing element and/or on the at least one second housing element, wherein the sealing material is in particular arranged in the region of the at least one first and/or second housing element which, in the closed position, is in contact with the at least one second or first housing element respectively, the probability of the escape of substances from the interior of the battery system and the probability of the penetration of substances into the interior of the battery system are reduced. This leads to an increase in safety when handling the battery system and ensures the suitability of use of a battery system. The sealing material is in particular rubber and/or polytetrafluoroethylene and/or nitrile rubber and/or ethylene-propylene-diene rubber and/or an adhesive sealant, for example a silicone-based adhesive sealant, an acrylic-based adhesive sealant and/or a butyl-based adhesive sealant.

According to a next preferred embodiment of the disclosure, the hinge has a device, wherein the device is suitable for setting an angle through which the at least one first housing element and/or the at least one second housing element can be moved about the rotation axis. Because, according to the disclosure, the hinge has a device, wherein the device is suitable for setting an angle through which the at least one first housing element and/or the at least one second housing element can be moved about the rotation axis, safety when handling the battery system is increased. The reason for the increase in safety when handling the battery system is that it is not possible for the battery system to unfold, i.e. for the at least one first housing element and/or the at least one second housing element to rotate beyond a particular angle. Because it is possible to set the angle through which the at least one first housing element and/or the at least one second housing element can be moved about the rotation axis, unintentional closure of the two housing elements is not possible. In addition, because the at least one first housing element and/or the at least one second housing element can assume a stable end position in the unfolded state, wherein the at least one first or the at least one second housing element may for example be locked stably in this end position, removal of a housing element is unnecessary, whereby furthermore incorrect reassembly of the two housing element is avoided.

According to a next preferred embodiment of the disclosure, a locking device, suitable for holding the at least one first housing element and/or the at least one second housing element in the closed position, is arranged on the at least one first housing element and/or the at least one second housing element.

Because, according to the disclosure, a locking device suitable for holding the at least one first housing element and/or the at least one second housing element in the closed position, is arranged on the at least one first housing element and/or on the at least one second housing element, an undesirable rotation of the at least one first housing element and/or the at least one second housing element is avoided. This leads to an increase in safety when using the battery system.

### BRIEF DESCRIPTION OF THE DRAWINGS

The disclosure is now described below with reference to exemplary embodiments, from which further inventive features may arise and to which however the disclosure is not restricted in scope. The exemplary embodiments are shown in the figures.

The drawings show:

FIG. 1 the diagrammatic depiction of a battery system according to the disclosure in a first embodiment;

FIG. 2 the diagrammatic depiction of a battery system according to the disclosure in a second embodiment;

FIG. 3 the diagrammatic depiction of a battery system according to the disclosure in a third embodiment.

### DETAILED DESCRIPTION

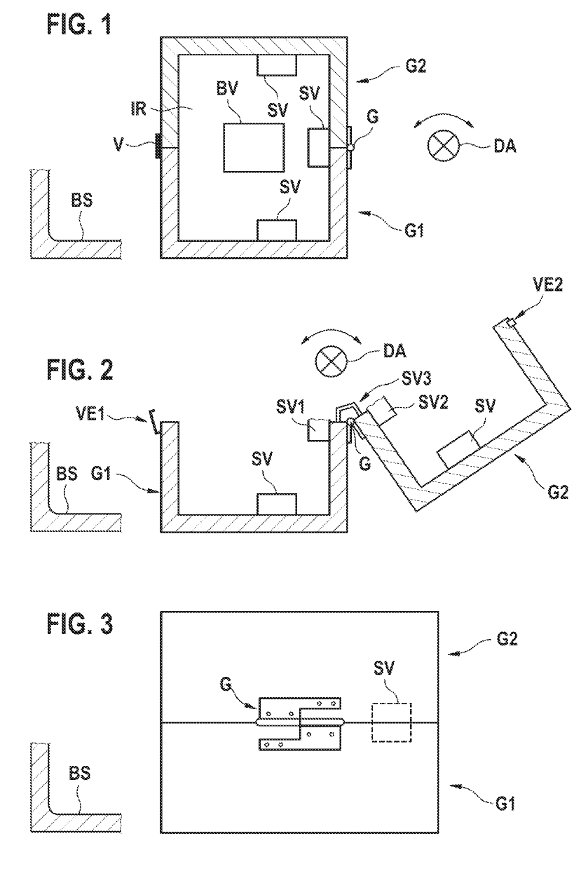

FIG. 1 shows a diagrammatic depiction of a battery system according to the disclosure in a first embodiment, in a state in which an at least one first housing element and an at least one second housing element are in a closed position. The battery system is designated BS. G1 indicates the at least one first housing element, G2 the at least one second housing element. The at least one first housing element G1 and the at least one second housing element G2 are in a closed position, such that the at least one first housing element G1 and the at least one second housing element G2 form a common closed interior. The interior is designated IR. A battery device designated BV may be arranged inside the interior IV. G designates a hinge, wherein the hinge connects the at least one first housing element G1 and the at least one second housing element G2, and is suitable for moving the at least one first housing element G1 and/or the at least one second housing element G2. DA designates a rotation axis. The at least one first housing element G1 and/or the at least one second housing element G2 are able to rotate about the common rotation axis DA by means of the common connected hinge G. V designates a locking device, wherein the locking device V is suitable for holding the at least one first housing element G1 and/or the at least one second housing element G2 in the closed position. The locking device V is arranged on the at least one first housing element G1 and/or on the at least one second housing element G2. SV indicates a closing device. The closing device SV is suitable for automatically moving the at least one first housing element G1 and/or the at least one second housing element G2 into the closed position about the common rotation axis DA. The closing device SV may be arranged on the at least one first housing element G1 and/or on the at least one second housing element G2. The closing device SV may furthermore be arranged inside the interior IR and opposite the hinge G.

FIG. 2 shows diagrammatically a battery system according to the disclosure in a second embodiment. In contrast to the diagrammatic depiction of the battery system BS shown in FIG. 1, the at least one first housing element G1 and the at least one second housing element G2 have not assumed the closed position. According to the embodiment of the battery system BS according to the disclosure shown in FIG. 2, the locking device V is in an open position. The locking device V here comprises a first locking element VE1 and a second locking element VE2. The first locking element VE1 is arranged on the at least one first housing element G1. The second locking element VE2 is arranged on the at least one second housing element G2. According to the embodiment shown in FIG. 2, the locking element VE1 is for example a hook and the locking element VE2 is for example an eye, wherein the hook can be engaged in the eye. SV designates a closing device. The closing device SV is suitable for automatically moving the at least one first housing element G1 and/or the at least one second housing element G2 about the common rotation axis DA into the closed position. The closing device SV may be arranged on the at least one first housing element G1 and/or on the at least one second housing element G2. The closing device SV may furthermore be formed from components which are arranged on the at least one first housing element Gl, on the at least one second housing element G2, and between the housing elements G1 and G2. The component arranged on the at least one first housing element G1 is designated SV1, the component arranged on the at least one second housing element G2 is designated SV2, and the component arranged between the housing elements G1 and G2 is designated SV3. According to the embodiment shown in FIG. 2, by means of the component SV3, a force may be exerted on the housing elements G1 and G2 which causes a rotation of the housing elements G1 and G2 about the rotation axis DA by means of the common connecting hinge G.

FIG. 3 shows diagrammatically a battery system according to the disclosure in a third embodiment. According to this embodiment, the at least one first housing element G1 and the at least one second housing element G2 are shown in the state in which the at least one first housing element G1 and the at least one second housing element G2 are in a closed position. In contrast to the diagrammatic depiction of the battery system shown in FIG. 1, the two sides of the at least one first housing element G1 and the at least one second housing element G2 are depicted diagrammatically in frontal view, such that the hinge G is also shown diagrammatically in frontal view.

SV designates a closing device. The closing device SV is suitable for automatically moving the at least one first housing element G1 and/or the at least one second housing element G2 about the common rotation axis DA into the closed position. According to the embodiment shown in FIG. 3, the closing device SV may be arranged next to the hinge G on both housing elements G1 and G2.

What is claimed is:

1. A battery system, comprising:
at least one battery device;
at least one first housing element and at least one second housing element that have a common connecting hinge that enables moving at least one of the at least one first housing element and the at least one second housing element about a common rotation axis, the at least one first housing element and the at least one second housing element configured to:
receive the at least one battery device; and
move into a closed position whereat the at least one first housing element and the at least one second housing element define a common closed interior; and
a closing device configured to automatically move at least one of the at least one first housing element and the at least one second housing element about the common rotation axis into the closed position.

2. The battery system of claim 1, wherein the closing device is integrated into the hinge.

3. The battery system of claim 1, wherein the closing device is a traction device or a pressure device.

4. The battery system of claim 3, wherein the traction device includes a spring.

5. The battery system of claim 1, wherein the closing device is a vacuum device.

6. The battery system of claim 1, further comprising:
a sealing material disposed on at least one of the at least one first housing element and the at least one second housing element.

7. The battery system of claim 1, wherein the hinge includes an angling device configured to set an angle to delimit motion of at least one of the at least one first housing element and the at least one second housing element about the common rotation axis.

8. The battery system of claim 1, further comprising:
a locking device that is configured to hold at least one of the at least one first housing element and the at least one second housing element in the closed position, and that is positioned on at least one of the at least one first housing element and the at least one second housing element.

9. A method of using a battery system that includes at least one battery device, at least one first housing element and at least one second housing element that have a common connecting hinge that enables moving at least one of the at least one first housing element and the at least one second housing element about a common rotation axis, the at least one first housing element and the at least one second housing element configured to receive the at least one battery device and move into a closed position whereat the at least one first housing element and the at least one second housing element define a common closed interior, and a closing device configured to automatically move at least one of the at least one first housing element and the at least one second housing element about the common rotation axis into the closed position, the method comprising:
using the battery system in a vehicle.

10. The battery system of claim 1, wherein the battery system is a lithium-ion battery system.

11. The battery system of claim 4, wherein the spring is a coil spring.

12. The battery system of claim 6, wherein the sealing material is disposed in a region of at least one of the at least one first housing element and the at least one second housing element that is in contact with the at least one second housing element and the at least one first housing element, respectively.

13. The method of claim 9, wherein the vehicle is a motor vehicle.
